(19) United States
(12) Patent Application Publication
(10) Pub. No.: US 2025/0141308 A1
(43) Pub. Date: May 1, 2025

(54) MULTIZONE HEAT TRANSFER SYSTEM

(71) Applicant: Garrett Transportation I Inc., Torrance, CA (US)

(72) Inventor: Valeriy Fedorikhin, Redondo Beach, CA (US)

(73) Assignee: Garrett Transportation I Inc., Torrance, CA (US)

(21) Appl. No.: 18/494,816

(22) Filed: Oct. 26, 2023

(51) Int. Cl. H02K 9/22; B33Y 10/00; B33Y 80/00; F02B 39/10; F04D 17/10; F04D 25/06; F04D 29/58; H02K 11/33

(52) U.S. Cl. CPC H02K 9/227; B33Y 80/00; F02B 39/10; F04D 17/10; F04D 25/06; F04D 29/582; H02K 11/33; B33Y 10/00

(57) ABSTRACT

A heat transfer system including a fluid conduit having an interior portion for routing a coolant and an outer portion physically isolated from the coolant, a first heatsink thermally coupled to the fluid conduit at a first position on the interior portion of the fluid condition wherein the first heatsink has a first flow resistance, a second heatsink thermally coupled to the fluid conduit a second position on the interior portion of the fluid conduit wherein the second heatsink has a second flow resistance greater than the first flow resistance, and an electronic component thermally coupled at the second position on the exterior portion of the fluid channel adjacent to the second heatsink.

### TECHNICAL FIELD

The present disclosure generally relates to heat transfer systems constructed using additive manufacturing and, more particularly, relates to the use of additive manufacturing to construct custom heat transfer structures having multiple colling regions configured to maximize heat transfer at critical locations while reducing pressure drop across the entire heat transfer system.

### BACKGROUND

Additive manufacturing (AM), also known as 3D printing, has transformed heatsink technologies by increasing freedom of design choices, broadened material choices and has helped to reduce weight and cost. AM allows for the creation of complex and intricate heatsink designs that would be difficult or impossible to manufacture using traditional methods. This can lead to improved heat dissipation performance. AM can be used to create heatsinks from a variety of materials, including metals, plastics, and composites. This allows for the selection of the material that best meets the specific needs of the application. AM can be used to create heatsinks that are lighter than those made using traditional methods. This can be a major advantage in applications where weight is a critical factor, such as aerospace and defense.

AM can be used to create microchannel heatsinks, which have a network of tiny channels that allow for efficient heat transfer. These heatsinks are often used in high-performance electronics where heat dissipation is critical. AM can be used to create lattice structures, which are lightweight and porous structures that have a high surface area. These structures are often used in heatsinks to improve heat dissipation performance. AM can be used to optimize the design of heatsinks for specific applications. This is done by using computer algorithms to find the design that provides the best balance of weight, cost, and heat dissipation performance. Overall, AM is a promising technology that has the potential to revolutionize the design and manufacturing of heatsinks. It is already being used to create innovative and efficient heatsinks for a variety of applications. Thus, it is desirable to provide an efficient heat transfer that balances surface area and coolant flow to optimize heat transfer between the heat transfer system and the coolant. Other desirable features and characteristics of the present disclosure will become apparent from the subsequent detailed description and the appended claims, taken in conjunction with the accompanying drawings and this background discussion.

### BRIEF SUMMARY

In one embodiment, a heat transfer system including a fluid conduit having an interior portion for routing a coolant and an outer portion physically isolated from the coolant, a first heatsink thermally coupled to the fluid conduit at a first position on the interior portion of the fluid condition wherein the first heatsink has a first flow resistance, a second heatsink thermally coupled to the fluid conduit a second position on the interior portion of the fluid conduit wherein the second heatsink has a second flow resistance greater than the first flow resistance, and an electronic component thermally coupled at the second position on the exterior portion of the fluid channel adjacent to the second heatsink.

In another embodiment, a method of manufacturing a heat transfer system including providing a fluid conduit having an interior portion for routing a coolant and an outer portion physically isolated from the coolant, forming a first heatsink having a first flow resistance at a first position on the interior portion of the fluid conduit such that the first heatsink is thermally coupled to the fluid conduit, forming a second heatsink having a second flow resistance at a second position on the interior portion of the fluid conduit such that the second heatsink is thermally coupled to the fluid conduit and wherein the second flow resistance is greater than the first flow resistance, and affixing an electronic component at the second position on the exterior portion of the fluid channel adjacent to the second heatsink such that the electronic component is thermally coupled to the fluid conduit and the second heatsink.

A turbocharger system including an electric motor configured for rotating a shaft mechanically coupled to a compressor wheel, a controller for controlling a rotation of the electric motor, the controller including a control circuit and a MOSFET, a fluid conduit for removing heat from the controller, the fluid conduit having an interior portion for routing a coolant and an outer portion physically isolated from the coolant and wherein the controller is thermally coupled to the fluid condition on the outer portion of the fluid conduit, a first heatsink thermally coupled to the fluid conduit at a first position on the interior portion of the fluid condition adjacent to the control circuit, wherein the first heatsink has a first flow resistance, and a second heatsink thermally coupled to the fluid conduit at a second position on the interior portion of the fluid conduit adjacent to the MOSFET, wherein the second heatsink has a second flow resistance greater than the first flow resistance.

### BRIEF DESCRIPTION OF THE DRAWINGS

The present disclosure will hereinafter be described in conjunction with the following drawing figures, wherein like numerals denote like elements, and wherein:

FIG. 1 is a schematic illustration of an engine system with a fluid compressor device that includes an integrated controller according to exemplary embodiments of the present disclosure;

FIG. 2 illustrates an exemplary housing for use of a multi zone thermal transfer system constructed via additive manufacturing techniques according to exemplary embodiments of the present disclosure;

FIG. 3 illustrates a cross sectional view of a thermal transfer system for use of a multi zone thermal transfer system constructed via additive manufacturing techniques according to exemplary embodiments of the present disclosure;

FIG. 4 illustrates a cross sectional view of an alternative thermal transfer system for use of a multi zone thermal transfer system constructed via additive manufacturing techniques according to exemplary embodiments of the present disclosure; and

FIG. 5 illustrates an exemplary method for manufacturing a heat transfer system according to exemplary embodiments of the present disclosure.

### DETAILED DESCRIPTION

The following detailed description is merely exemplary in nature and is not intended to limit the present disclosure or the application and uses of the present disclosure. Furthermore, there is no intention to be bound by any theory presented in the preceding background or the following detailed description.

Air flow affects cooling in a heatsink by increasing the rate of heat transfer from the heatsink to the surrounding air because the faster the air flows over the heatsink, the more heat can be carried away by the air. Likewise, the surface area of a heatsink affects cooling by increasing the amount of heat that can be transferred to the surrounding air. The more surface area there is, the more heat can be transferred through conduction and convection.

Increased surface area for heatsinks will generally have a better cooling performance. However, the larger surface areas often can restrict air flow over the heatsink, reducing the cooling system's ability to move heated coolant away from the heatsink structure. For example, aggressive space constraints placed on power electronics being wrapped around e-turbo motors can create a challenge for creating curved heatsinks and very small heatsinks for power electronics that can both provide very high surface area pins right around the MOSFETs (very high heat loss components) and have relatively open “free flow’ zones where lots of heat transfer is not needed. As MOSFET power densities go up, traditional casting methods many not be able to provide the needed super fine pin densities for high heat transfer.

AM metal printing can be used to deliver super fine geometries in the exact locations where they are needed and create a cooling structure as a single piece, eliminating seals, welds and material discontinuities. AM can be employed to simplify heatsinks, reduce leakage risks by consolidating many parts into a single part and balance thermal performance to pressure drop in a superior manner as compared to cast heatsinks.

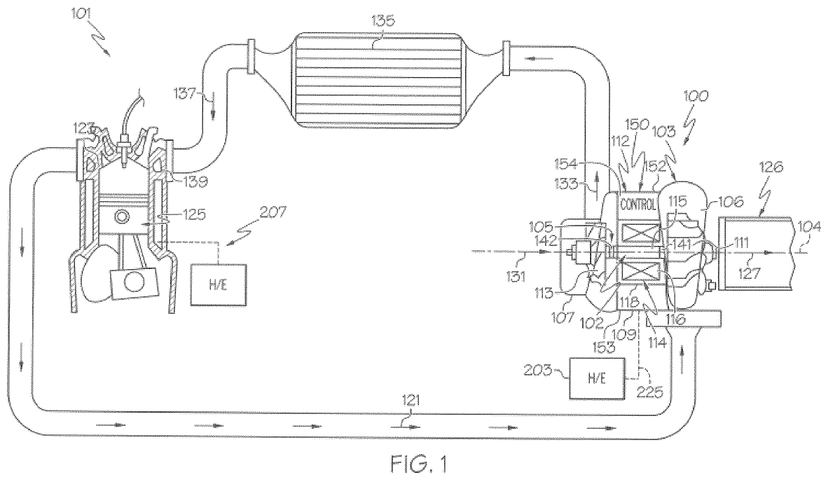

FIG. 1 is a schematic view of an example turbomachine, such as a turbocharger 100 that is incorporated within an engine system 101 and that includes one or more features of the present disclosure. It will be appreciated that the turbocharger 100 could be another turbomachine (e.g., a supercharger, a turbine-less compressor device, etc.) in additional embodiments of the present disclosure. Furthermore, the turbomachine of the present disclosure may be incorporated into a number of systems other than an engine system without departing from the scope of the present disclosure. For example, the turbomachine of the present disclosure may be incorporated within a fuel cell system for compressing air that is fed to a fuel cell stack, or the turbomachine may be incorporated within another system without departing from the scope of the present disclosure.

Generally, the turbocharger 100 may include a housing 103 and a rotating group 102, which is supported within the housing 103 for rotation about an axis 104 by a bearing system 105. The bearing system 105 may be of any suitable type, such as a roller-element bearing or an air bearing system. As shown in the illustrated embodiment, the housing 103 may include a turbine housing 106, a compressor housing 107, and an intermediate housing 109. The intermediate housing 109 may be disposed axially between the turbine and compressor housings 106, 107.

Additionally, the rotating group 102 may include a turbine wheel 111, a compressor wheel 113, and a shaft 115. The turbine wheel 111 is located substantially within the turbine housing 106. The compressor wheel 113 is located substantially within the compressor housing 107. The shaft 115 extends along the axis of rotation 104, through the intermediate housing 109, to connect the turbine wheel 111 to the compressor wheel 113. Accordingly, the turbine wheel 111 and the compressor wheel 113 may rotate together as a unit about the axis 104.

The turbine housing 106 and the turbine wheel 111 cooperate to form a turbine stage (i.e., turbine section) configured to circumferentially receive a high-pressure and high-temperature exhaust gas stream 121 from an engine, specifically, from an exhaust manifold 123 of an internal combustion engine 125. The turbine wheel 111 and, thus, the other components of the rotating group 102 are driven in rotation around the axis 104 by the high-pressure and high-temperature exhaust gas stream 121, which becomes a lower-pressure and lower-temperature exhaust gas stream 127 that is released into a downstream exhaust pipe 126.

The compressor housing 107 and compressor wheel 113 form a compressor stage (i.e., compressor section). The compressor wheel 113, being driven in rotation by the exhaust-gas driven turbine wheel 111, is configured to compress received input air 131 (e.g., ambient air, or already-pressurized air from a previous-stage in a multi-stage compressor) into a pressurized airstream 133 that is ejected circumferentially from the compressor housing 107. The compressor housing 107 may have a shape (e.g., a volute shape or otherwise) configured to direct and pressurize the air blown from the compressor wheel 113. Due to the compression process, the pressurized air stream is characterized by an increased temperature, over that of the input air 131.

The pressurized airstream 133 may be channeled through an air cooler 135 (i.e., intercooler), such as a convectively cooled charge air cooler. The air cooler 135 may be configured to dissipate heat from the pressurized airstream 133, increasing its density. The resulting cooled and pressurized output air stream 137 is channeled into an intake manifold 139 of the internal combustion engine 125, or alternatively, into a subsequent-stage, in-series compressor.

Furthermore, the turbocharger 100 may include an e-machine stage 112. The e-machine stage 112 may be cooperatively defined by the intermediate housing 109 and by an e-machine 114 housed therein. The shaft 115 may extend through the e-machine stage 112, and the e-machine 114 may be operably coupled thereto. The e-machine 114 may be an electric motor, an electric generator, or a combination of both. Thus, the e-machine 114 may be configured as a motor to convert electrical energy to mechanical (rotational) energy of the shaft 115 for driving the rotating group 102. Furthermore, the e-machine 114 may be configured as a generator to convert mechanical energy of the shaft 115 to electrical energy that is stored in a battery, etc. As stated, the e-machine 114 may be configured as a combination motor/generator, and the e-machine 114 may be configured to switch functionality between motor and generator modes in some embodiments as well.

For purposes of discussion, the e-machine 114 will be referred to as a motor 116. The motor 116 may include a rotor member (e.g., a plurality of permanent magnets) that are supported on the shaft 115 so as to rotate with the rotating group 102. The motor 116 may also include a stator member (e.g., a plurality of windings, etc.) that is housed and supported within the intermediate housing 109. In some embodiments, the motor 116 may be disposed axially between a first bearing 141 and a second bearing 142 of the bearing system 105. Also, the motor 116 may be housed by a motor housing 118 of the intermediate housing 109. The motor housing 118 may be a thin-walled or shell-like housing that encases the stator member of the motor 116. The motor housing 118 may also encircle the axis 104, and the shaft 115 may extend therethrough.

Furthermore, the turbocharger 100 may include an integrated controller 150. The integrated controller 150 may generally include a controller housing 152 and a number of internal components 154 (e.g., circuitry, electronic components, cooling components, support structures, etc.) housed within the controller housing 152. The integrated controller 150 may control various functions. For example, the integrated controller 150 may control the motor 116 to thereby control certain parameters (torque, angular speed, START/STOP, acceleration, etc.) of the rotating group 102. The integrated controller 150 may also be in communication with a battery, an electrical control unit (ECU), or other components of the respective vehicle in some embodiments. More specifically, the integrated controller 150 may receive DC power from a vehicle battery, and the integrated controller 150 may convert the power to AC power for controlling the motor 116. In additional embodiments wherein the e-machine 114 is a combination motor/generator, the integrated controller 150 may operate to switch the e-machine 114 between its motor and generator functionality.

In some embodiments, the integrated controller 150 may be disposed axially between the compressor stage and the turbine stage of the turbocharger 100 with respect to the axis 104. Thus, as illustrated, the integrated controller 150 may be disposed and may be integrated proximate the motor 116. For example, as shown in the illustrated embodiment, the integrated controller 150 may be disposed on and may be arranged radially over the motor housing 118. More specifically, the integrated controller 150 may extend and wrap about the axis 104 to cover over the motor 116 such that the motor 116 is disposed radially between the shaft 115 and the integrated controller 150. The integrated controller 150 may also extend about the axis 104 in the circumferential direction and may cover over, overlap, and wrap over at least part of the motor housing 118. In some embodiments, the integrated controller 150 may wrap between approximately forty-five degrees (45°) and three-hundred-sixty-five degrees (365°) about the axis 104.

As illustrated, the housing 152 may generally be arcuate so as to extend about the axis 104 and to conform generally to the rounded profile of the turbocharger 100. The housing 152 may also be an outer shell-like member that is hollow and that encapsulates the internal components 154. Electrical connectors may extend through the housing 152 for electrically connecting the internal components 154. Furthermore, there may be openings for fluid couplings (e.g., couplings for fluid coolant). Additionally, the controller housing 152 may define part of the exterior of the turbocharger 100. An outer surface 153 of the controller housing 152 may extend about the axis 104 and may face radially away from the axis 104. The outer surface 153 may be at least partly smoothly contoured about the axis 102 as shown, or the outer surface 153 may include one or more flat panels that are arranged tangentially with respect to the axis 104 (e.g., a series such flat panels that are arranged about the axis 104). The outer surface 153 may be disposed generally at the same radius as the neighboring compressor housing 107 and/or turbine housing 106. Accordingly, the overall size and profile of the turbocharger 100, including the controller 150, may be very compact.

The internal components 154 may be housed within the controller housing 152. Also, at least some of the internal components 154 may extend arcuately, wrap about, and/or may be arranged about the axis 104 as will be discussed. Furthermore, as will be discussed, the internal components 154 may be stacked axially along the axis 104 in close proximity such that the controller 150 is very compact. As such, the integrated controller 150 may be compactly arranged and integrated with the turbine stage, the compressor stage, and/or other components of the turbocharger 100. Also, internal components 154 of the controller 150 may be in close proximity to the motor 116 to provide certain advantages. For example, because of this close proximity, there may be reduced noise for more efficient control of the motor 116.

Furthermore, the controller 150 may include a number of components that provide robust support and that provide efficient cooling. Thus, the turbocharger 100 may operate at extreme conditions due to elevated temperatures, mechanical loads, electrical loads, etc. Regardless, the controller 150 may be tightly integrated into the turbocharger 100 without compromising performance.

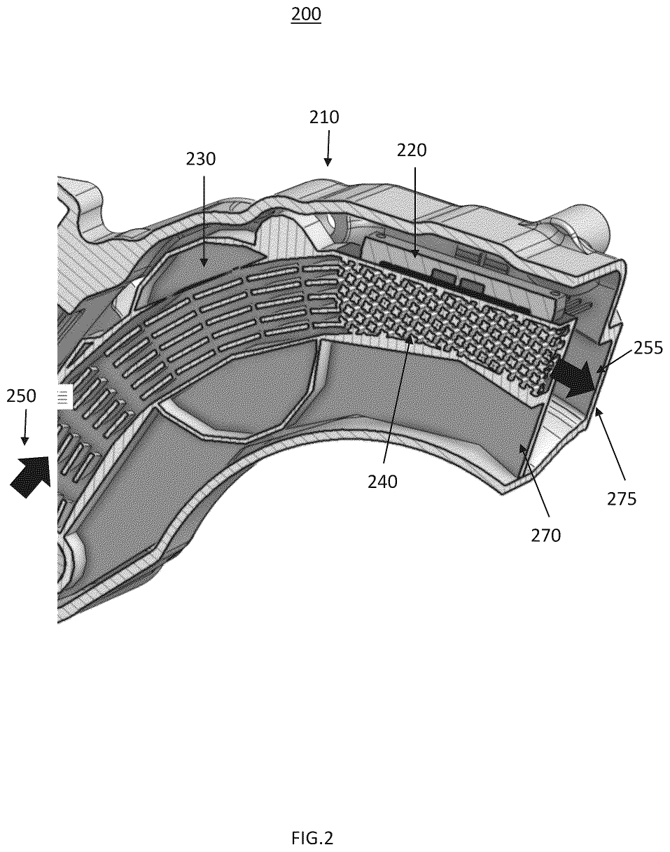

Turning now to FIG. 2, an exemplary housing 200 for use of a multi zone thermal transfer system constructed via additive manufacturing techniques according to an exemplary embodiment of the present disclosure is shown. The exemplary housing 200 includes a thermally conductive structure 210, an electronic circuit 220, a first portion of a heatsink 230 and a second portion of a heatsink 240.

In some exemplary embodiments, the housing 200 may include a metallic, thermally conductive structure for providing protection to enclosed components and providing mounting surfaces for internal and external components. The housing 200 can further provide conduits for coolants, lubricants, and other fluids or gases. The electronic circuit 220 may form a portion of the controller 150 of FIG. 1. The electronic circuit 220 can include high voltage, high temperature components, such as metal oxide semiconductor field-effect transistors (MOSFETs) for providing switched electric currents to the motor 116 of FIG. 1. These high voltage, high temperature components require highly efficient cooling capabilities in order to operate efficiently, particularly in a high temperature environment such as in conjunction with an internal combustion engine and/or a turbocharger.

The exemplary thermal transfer system can include two or more portions, wherein each portion has different configurations allowing for individualized cooling characteristics and airflow impedance. Portions requiring lower thermal transfer can have heatsinks with lower surface area and lower airflow impedance. In heatsinks, increased surface area and increased airflow results can result in more heat being removed from the heatsink. However, increasing surface area of the heatsink restricts airflow and results in increased airflow resistance. Balancing the surface area and airflow to achieve optimal cooling efficiency is desirable in a thermal transfer system.

To achieve this optimal cooling efficiency, multiple cooling zones are proposed. These cooling zones can be manufactured to provide a required surface area and airflow resistance to provide a desired thermal transfer for each of the cooling zones. For example, the exemplary thermal transfer system includes a first portion of a heatsink 230 and a second portion of a heatsink 240. In some exemplary embodiments, a first cooling zone corresponding to the first portion of the heatsink 230 may demand less cooling performance, and therefore the surface area of the first portion of the heatsink 230 can be reduced, thereby reducing airflow impedance in the first portion of the heatsink 230. Conversely, a second cooling zone corresponding to a second portion of the heatsink 240, can require greater cooling performance. In response to the increased cooling demand, the second portion of the heatsink 240 can be manufactured with increased surface area to accommodate the increased thermal transfer. This increased surface area can result in reduced airflow. It is desirable to minimize airflow impedance in areas where less thermal transfer is required in order to reduce the total airflow impedance of the overall thermal transfer system, thereby maintaining a sufficient airflow in the areas requiring increased thermal transfer.

In some exemplary embodiments, a cold cooling fluid 250, such as a gas or a liquid, is passed into the thermal transfer system, allowing the heat from the first portion of the heatsink 230 and the second portion of the heatsink 240 to be transferred to the cooling fluid 250 through the fins of the heatsink. The increased surface area of the heatsinks allows the heat to be transferred to the air more efficiently. Convection is the transfer of heat through the movement of fluids. As the cold cooling fluid 250 flows through the heatsink structures, it carries away the heat. The faster the cold cooling fluid 250 flows, the more heat can be carried away. The resulting warmed cooling fluid 275 then exits the thermal transfer system and is either released into the environment, such as in air cooled systems, or directed to another heat transfer system to remove some of the heat within the cooling fluid where it can be returned to the thermal transfer system as the cold cooling fluid 250.

Thermal control systems can be manufactured using an AM technique to provide complex structures having a maximum surface area while reducing airflow restrictions. In some exemplary embodiments, one or more portions of the overall housing 200 can be manufactured using AM techniques where complex structures are desired and then assembled with other cast, stamped or machined parts. For example, an inner portion 270 of the housing 200 including the first portion of the heatsink 230 and the second portion of the heatsink 240 can be formed using AM techniques as the complex structures of the second portion of the heatsink 240 can only be achieved using AM. The outer portion 275 of the housing 200 can be formed using conventional stamped or casting manufacturing techniques and the two pieces can then be combined to fabricate the complete housing 200.

Low flow impedance heatsink structures can be located in areas of the thermal transfer system requiring less thermal transfer capacity and high flow impedance heatsink structures can be located in areas of the heat transfer system requiring greater thermal transfer capacity. As is illustrated by the exemplary housing 200 employing the multi zone thermal transfer system, the first portion of the heatsink 230 is created using fins oriented parallel to the flow of the cooling fluid. These fins result in minimal flow impedance for the cooling fluid, but have a reduce thermal transfer capacity. This facilitates a maintained cooling fluid flow rate when the cooling fluid reaches the second portion of the heatsink 240. The second portion of the heatsink 240 has a more complex lattice structure to increase the thermal transfer capacity of the second portion of the heatsink 240, but results in an increased flow impedance at the second portion of the heatsink 240. In this exemplary embodiment, the increased thermal transfer capacity is required to cool the collocated electronic circuit 220. Overall, the total flow impedance of the exemplary thermal transfer system is less than a thermal transfer system having heatsinks entirely composed of the more complex lattice structure.

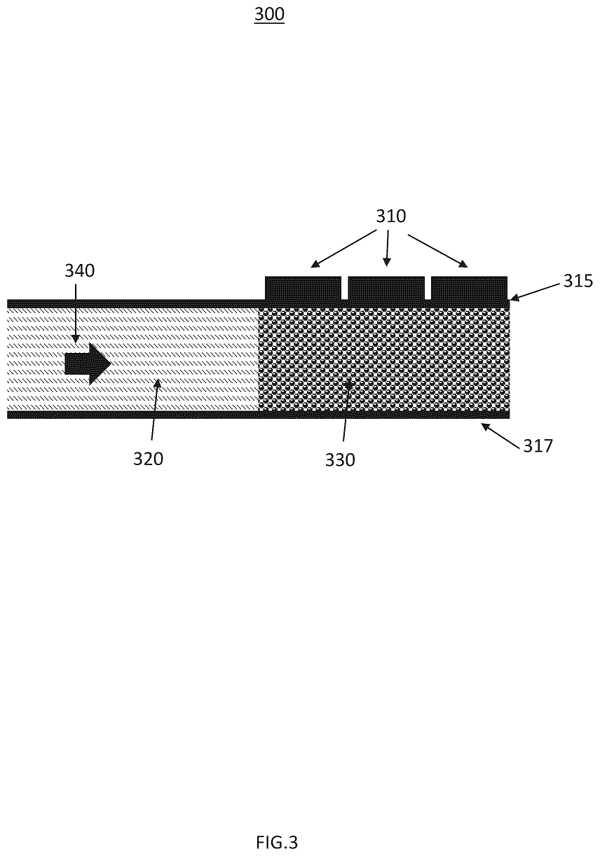

Referring now to FIG. 3, a cross sectional view of a thermal transfer system 300 for use of a multi zone thermal transfer system constructed via additive manufacturing techniques according to an exemplary embodiment of the present disclosure is shown. The exemplary thermal transfer system 300 includes a plurality of high temperature electronic components 310, a first cooling region 320 and a second cooling region 330. The thermal transfer system 300 is configured to route a coolant 340 through the first cooling region 320 and the second cooling region 330 within a housing including an upper thermally conductive surface 315 and a lower thermally conductive surface 317.

In the exemplary thermal transfer system 300, the plurality of high temperature electronic components 310 are thermally coupled to the upper thermally conductive surface 315. In some exemplary embodiments, the high temperature electronic components 310 can include MOSFETS used to control the flow of current to the motor windings in three-phase motors, such as the motors used to drive electronic turbochargers. MOSFETs are used in three-phase motors applications due to their ability to handle high currents and voltages. During the switching operations, these MOSFETs generate high levels of heat which must be efficiently transferred away from the MOSFETs. In this exemplary thermal transfer system 300, the heat from the MOSFETs is coupled to the second cooling region 330 via upper thermally conductive surface 315. The second cooling region 330 is configured as a high surface area structure, such as a lattice structure or the like, to maximize thermal energy transfer to the coolant 340. The second cooling region 330 is located directly adjacent to the high temperature electronic components 310 to maximize thermal transfer efficiency between the high temperature electronic components 310 and the coolant 340.

The first cooling region 320 is configured for low coolant flow impedance. Low coolant flow impedance heatsink structures can have a smooth, unobstructed surface and a large flow passage area. Some of the most common heatsink structures with low airflow impedance include smooth plate fins or pin fins, or low-density lattice structures. Heatsinks with smooth fins have a lower coolant flow impedance than heatsinks with fins that have sharp edges or grooves as the smooth fins reduce turbulence in the coolant flow, thereby reducing the pressure drop. Heatsinks with wide flow passages also have a lower coolant flow impedance than heatsinks with narrow flow passages. This is because the wider flow passages allow the coolant to flow more freely, which reduces the pressure drop.

The second cooling region 330 can be fabricated with greater surface area concentration than the first cooling region 320. This greater surface area concentration provides more surface for the heatsink structure to transfer heat to the coolant, but also creates higher coolant flow impedance due to the narrower flow passages. Advantageously, the heatsink structure of the second cooling region 330 can be fabricated using AM to create complex three-dimensional structures to maximize surface area and minimize coolant flow impedance. Exemplary structures include lattice structures, such as microchannel, lattice or a triply periodic minimal surface structures. In some exemplary embodiments, the reduced coolant flow impedance of the first cooling region 320 allows for a minimized overall coolant flow impedance over the combined first cooling region 320 and the second cooling region 330 while facilitating maximum heat transfer between the high temperature electronic components 310 and the coolant 340.

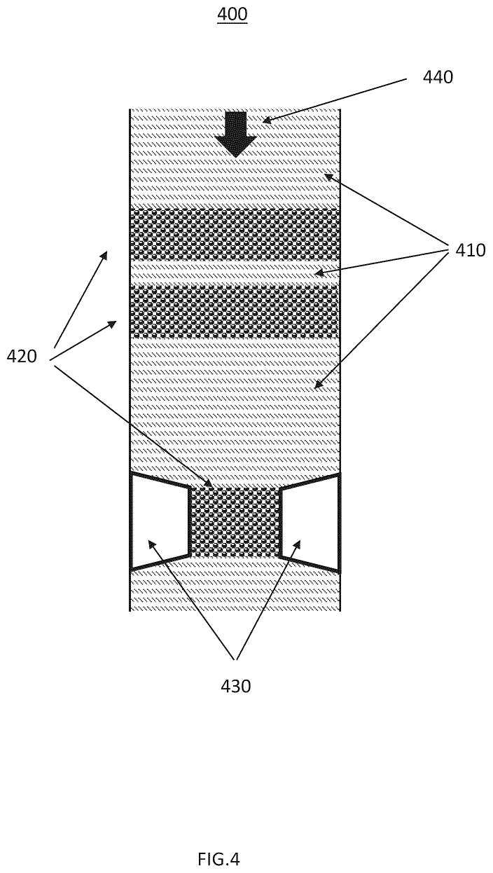

Turning now to FIG. 4, a cross sectional view of an alternative thermal transfer system 400 for use of a multi zone thermal transfer system constructed via additive manufacturing techniques according to an exemplary embodiment of the present disclosure is shown. The exemplary thermal transfer system 400 includes regions of low surface density heatsink structures 410 and high density heatsink structures 420. Coolant 440 flows through each of the regions and heat is transferred from the heatsink structures 410, 420 to the coolant 440. Although the direction of the coolant flow is illustrated as from top to bottom, coolant flow can be directed bottom to top through the thermal transfer system 400 in response to engineering design requirements.

In some exemplary embodiments, the thermal transfer system 400 can include high impedance portions 430 which have a higher flow impedance than the high density heatsink structures 420. In some exemplary embodiments, these high impedance portions 430 can be solid portions that allow no coolant flow through them and redirect coolant flow around them. The high impedance portions 430 can be thermally conductive structures which transfer heat from the solid portion 430 to the coolant 440 on the outer surfaces of the high impedance portions 430. In some exemplary embodiments, these high impedance portions 430 can be positioned such that coolant flow is directed towards one or more high density heatsink structures 420, reducing the cross-sectional area of the thermal transfer system 400 at the high density heatsink structures 420, thereby increasing the coolant flow rate through the high density heatsink structures 420.

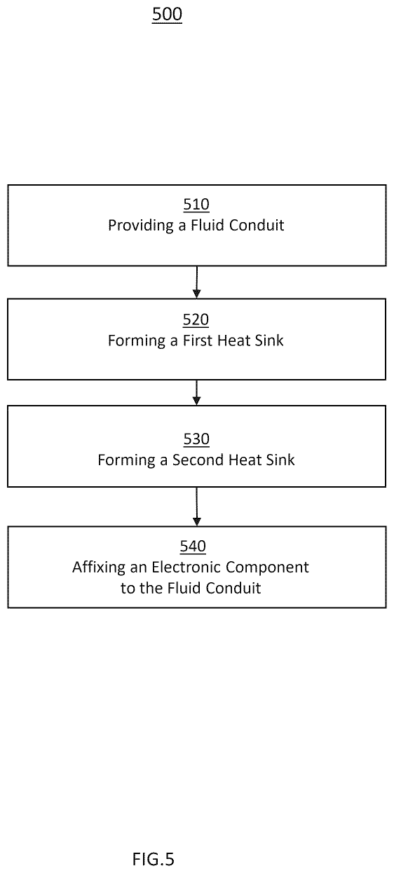

Turning now to FIG. 5, an exemplary method 500 for manufacturing a heat transfer system according to an exemplary embodiment is shown. The method is first configured for providing 510 a fluid conduit having an interior portion for routing a coolant and an outer portion physically isolated from the coolant. In some exemplary embodiments, the fluid conduit can form a portion of a turbocharger housing.

The method is next operative for forming 520 a first heatsink having a first flow resistance at a first position on the interior portion of the fluid conduit such that the first heatsink is thermally coupled to the fluid conduit. The first heatsink can be formed using an additive manufacturing process on, or within, the fluid conduit. Next, the method is operative for forming 530 a second heatsink having a second flow resistance at a second position on the interior portion of the fluid conduit such that the second heatsink is thermally coupled to the fluid conduit and wherein the second flow resistance is greater than the first flow resistance. In some exemplary embodiments, the first heatsink can be formed from a first lattice structure having a first plurality of channels and the second heatsink is formed from a second lattice structure having a second plurality of channels and wherein the second plurality of channels are narrower than the first plurality of channels. The first heatsink and the second heatsink can have different heatsink structures including pins, plates, lattice and other three-dimensional structures. For example, the first heatsink can be formed from a plurality of pins and the second heatsink is formed from a lattice structure having a plurality of channels.

The method is next operative for affixing 540 an electronic component at the second position on the exterior portion of the fluid channel adjacent to the second heatsink such that the electronic component is thermally coupled to the fluid conduit and the second heatsink. In some exemplary embodiments the first heatsink and the second hea sink are formed using an additive manufacturing system. For example, the first heatsink and the second heatsink are formed using a laser sintering process. Alternatively, the first heatsink and the second heatsink are formed using a fused deposition modeling process. In some exemplary embodiments, the fluid conduit, the first heatsink and the second heatsink can be formed during the same additive manufacturing process. Alternatively, the fluid conduit can be formed using an alternative manufacturing process, such as casting or stamping, and the first heatsink and the second heatsink can be formed during the same additive manufacturing process using the fluid conduit as a base for the additive manufacturing process.

In some exemplary embodiments, the method may be configured for forming a connecting portion for connecting the first heatsink and the second heatsink, wherein the first heatsink is configured to remove heat from the fluid conduit, the second heatsink is configured to remove heat from the electronic component. The connecting portion can then be configured to equalize the flow of heat between the first heatsink and the second heatsink. Likewise, the connecting portion enables heat from the electronic component to be thermally coupled from the second heatsink to the first heatsink to further improve the heat transfer capabilities of the heat transfer system.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the present disclosure in any way. Rather, the foregoing detailed description will provide those skilled in the art with a convenient road map for implementing an exemplary embodiment of the present disclosure. It is understood that various changes may be made in the function and arrangement of elements described in an exemplary embodiment without departing from the scope of the present disclosure as set forth in the appended claims.

What is claimed is:

1. A heat transfer system comprising:
a fluid conduit having an interior portion for routing a coolant and an outer portion physically isolated from the coolant;
a first heatsink thermally coupled to the fluid conduit at a first position on the interior portion of the fluid condition wherein the first heatsink has a first flow resistance;
a second heatsink thermally coupled to the fluid conduit a second position on the interior portion of the fluid conduit wherein the second heatsink has a second flow resistance greater than the first flow resistance; and
an electronic component thermally coupled at the second position on the exterior portion of the fluid channel adjacent to the second heatsink.

2. The heat transfer system of claim 1 wherein the coolant is a liquid coolant flowing in the fluid conduit through the first heatsink and the second heatsink.

3. The heat transfer system of claim 1 wherein the electronic component is a MOSFET.

4. The heat transfer system of claim 1 wherein the coolant is air flowing in the fluid conduit through the first heatsink and the second heatsink.

5. The heat transfer system of claim 1 wherein additive manufacturing is used to fabricate the fluid conduit, the first heatsink and the second heatsink.

6. The heat transfer system of claim 1 wherein the first heatsink includes a plurality of fins and the second heatsink includes a lattice structure.

7. The heat transfer system of claim 1 wherein the first heatsink includes a plurality of pins and the second heatsink includes a lattice structure.

8. The heat transfer system of claim 1 further including a solid portion for reducing a cross sectional area of the fluid conduit between the first heatsink and the second heatsink.

9. The heat transfer system of claim 1 wherein the fluid conduit has a first cross sectional area at the first heatsink and a second cross sectional area at the second heatsink and where the first cross sectional area is greater than the second cross sectional area.

10. A method of manufacturing a heat transfer system comprising:
providing a fluid conduit having an interior portion for routing a coolant and an outer portion physically isolated from the coolant;
forming a first heatsink having a first flow resistance at a first position on the interior portion of the fluid conduit such that the first heatsink is thermally coupled to the fluid conduit;
forming a second heatsink having a second flow resistance at a second position on the interior portion of the fluid conduit such that the second heatsink is thermally coupled to the fluid conduit and wherein the second flow resistance is greater than the first flow resistance; and
affixing an electronic component at the second position on the exterior portion of the fluid channel adjacent to the second heatsink such that the electronic component is thermally coupled to the fluid conduit and the second heatsink.

11. The method of manufacturing a heat transfer system of claim 10 wherein the first heatsink and the second hat sink are formed using an additive manufacturing system.

12. The method of manufacturing a heat transfer system of claim 10 wherein the first heatsink and the second heatsink are formed using a laser sintering process.

13. The method of manufacturing a heat transfer system of claim 10 wherein the first heatsink and the second heatsink are formed using fused deposition modeling process.

14. The method of manufacturing a heat transfer system of claim 10 further including a connecting portion for connecting the first heatsink and the second heatsink, wherein the first heatsink is configured to remove heat from a the fluid conduit, the second heatsink is configured to remove heat from the electronic component, and the connecting portion is configured to equalize the flow of heat between the first electronic component and the second electronic component.

15. The method of manufacturing a heat transfer system of claim 10 wherein the first heatsink is formed from a first lattice structure having a first plurality of channels and the second heatsink is formed from a second lattice structure having a second plurality of channels and wherein the second plurality of channels are narrower than the first plurality of channels.

16. The method of manufacturing a heat transfer system of claim 10 wherein the first heatsink is formed from a carbon fiber-reinforced polymer and the second heatsink is formed from a silicon carbide-reinforced polymer.

17. The method of manufacturing a heat transfer system of claim 10 wherein the first heatsink is formed from polymer matrix composite and the second heatsink is formed from one of an aluminum matrix composite, a copper matrix composite and a metal based composite.

18. The method of manufacturing a heat transfer system of claim 10 wherein the fluid conduit has a first cross sectional area at the first heatsink and a second cross sectional area at the second heatsink and where the first cross sectional area is greater than the second cross sectional area.

19. A turbocharger system comprising:
an electric motor configured for rotating a shaft mechanically coupled to a compressor wheel;
a controller for controlling a rotation of the electric motor, the controller including a control circuit and a MOSFET;
a fluid conduit for removing heat from the controller, the fluid conduit having an interior portion for routing a coolant and an outer portion physically isolated from the coolant and wherein the controller is thermally coupled to the fluid condition on the outer portion of the fluid conduit;
a first heatsink thermally coupled to the fluid conduit at a first position on the interior portion of the fluid condition adjacent to the control circuit, wherein the first heatsink has a first flow resistance; and
a second heatsink thermally coupled to the fluid conduit at a second position on the interior portion of the fluid conduit adjacent to the MOSFET, wherein the second heatsink has a second flow resistance greater than the first flow resistance.

20. The turbocharger system of claim 19 wherein the fluid conduit, the first heatsink and the second heatsink are formed using an additive manufacturing system.
